(19) United States
(12) Patent Application Publication
(10) Pub. No.: US 2006/0093000 A1
(43) Pub. Date: May 4, 2006

(54) Multiple-wavelength laser diode and method of fabricating the same

(75) Inventors: Ok-hyun Nam, Seoul (KR); Kyoung-ho Ha, Seoul (KR); Han-youl Ryu, Suwon-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electro-Mechanics Co., Ltd., Suwon-si (KR)

(21) Appl. No.: 11/220,789

(22) Filed: Sep. 8, 2005

(30) Foreign Application Priority Data
Nov. 3, 2004 (KR) 10-2004-0088901

(51) Int. Cl. H01S 5/00

(52) U.S. Cl. 372/43.01

(57) ABSTRACT

A multiple-wavelength laser diode (LD) and method of fabricating the same are provided. The multiple-wavelength LD includes at least three LDs, which are bonded onto a plate and aligned such that centers of emission points of the three LDs form a line. Also, the multiple-wavelength LD includes a first LD, an insulating layer disposed on a substrate that extends from the first LD, and at least a second LD and a third LD bonded onto the insulating layer. The first, second, and third LDs are aligned such that centers of emission points are aligned.

### CROSS-REFERENCE TO RELATED PATENT APPLICATION

This application claims the benefit of Korean Patent Application No. 10-2004-0088901, filed on Nov. 3, 2004, in the Korean Intellectual Property Office, the disclosure of which is incorporated herein in its entirety by reference.

### BACKGROUND OF THE INVENTION

1. Field of the Invention

The present invention relates to a multiple-wavelength laser diode (LD) and method of fabricating the same, and more particularly, to a multiple-wavelength LD, which reduces aberration, has high condensing efficiency, and facilitates heat radiation, and a method of fabricating the same.

2. Description of the Related Art

A compound semiconductor light emitting device, such as a light emitting diode (LED) or a semiconductor LD, converts an electric signal into light using the properties of a compound semiconductor and produces laser beams, which have been put to practical use in the fields of optical communications, multiple communications, and space communications. In particular, the semiconductor LD is being widely used as a light source for a data transmission unit or a data writing/reading unit in the field of communications, such as optical communications, or in apparatuses, such as compact disk players (CDPs) or digital versatile disk players (DVDPs).

In recent years, a blue-ray disk (BD) has been developed as the next-generation storage medium to take the place of a conventional compact disk (CD) or digital versatile disk (DVD), and there is a strong likelihood that the demand for the BD will greatly increase. An optical pickup for a BD is preferably compatible with the conventional CD or DVD such that the CD or DVD can reproduce or write data using the optical pickup for the BD. Specifically, an LD for a BD, an LD for a DVD, and an LD for a CD produce laser beams with different wavelengths, for example, bluish-purple, red, and infrared wavelengths. When optical pickups are separately prepared for the respective LDs, the entire optical pickup system becomes large and the cost of production increases. Therefore, it is desirable to embody a common optical pickup system to all the LDs for the BD, DVD, and CD. For the common optical pickup system, the three types of LDs should be integrally formed as a single package. In this case, to simplify the design of the optical pickup system, the three LDs should be arrayed as close to each other as possible. Although a conventional technique proposes a structure in which LDs for a BD, a DVD, and a CD are integrally formed as a single package, the distance between two adjacent LDs is very large. This conventional structure exhibits low condensing efficiency and causes much aberration. Also, the conventional technique leads the entire optical pickup system to increase in size and the need for a complicated design. Further, the conventional structure in which the three LDs are integrally formed does not include an effective unit that facilitates the radiation of heat generated from the LDs. As a result, the internal temperatures of the LDs are raised so that the lifetimes of the LDs may be shortened.

### SUMMARY OF THE INVENTION

The present invention provides a multiple-wavelength laser diode (LD), which reduces aberration, exhibits high condensing efficiency, and facilitates heat radiation, and a method of fabricating the same.

According to an aspect of the present invention, there is provided a multiple-wavelength LD including at least a first LD, a second LD, and a third LD that are bonded onto a plate and are aligned such that centers of emission points of the first, second, and third LDs are aligned. In this embodiment, the plate may be selected from the group consisting of AlN, SiC, and a metal.

The first LD may include a first laser oscillation layer including a first resonant layer and a first n-type compound semiconductor layer and a first p-type compound semiconductor layer disposed on both surfaces of the first resonant layer; a first n-type electrode layer and a first p-type electrode layer disposed on both surfaces of the first laser oscillation layer; and a bonding metal layer disposed on one surface of at least one of the first n-type electrode layer and the first p-type electrode layer.

The first p-type compound semiconductor layer may include a first p-type contact layer disposed on the first p-type electrode layer and formed of GaN; and a first p-type clad layer disposed on the first p-type contact layer and formed of AlGaN. The first resonant layer may include a first active layer formed of InGaN; and first waveguide layers disposed on and under the first active layer and formed of InGaN. Also, the first n-type compound semiconductor layer may include a first n-type clad layer disposed on the first resonant layer and formed of AlGaN; a first buffer layer disposed on the first n-type clad layer and formed of GaN; and a GaN substrate stacked on the first buffer layer.

The second LD may include a second laser oscillation layer including a second resonant layer and a second n-type compound semiconductor layer and a second p-type compound semiconductor layer disposed on both surfaces of the second resonant layer; a second n-type electrode layer and a second p-type electrode layer disposed on both surfaces of the second laser oscillation layer; and a bonding metal layer disposed on one surface of at least one of the second n-type electrode layer and the second p-type electrode layer.

The second p-type compound semiconductor layer may include a second p-type contact layer disposed on the second p-type electrode layer and formed of GaAs; and a second p-type clad layer disposed on the second p-type contact layer and formed of AlGaInP. The second resonant layer may include a second active layer formed of AlGaInP; and second waveguide layers disposed on and under the second active layer and formed of AlGaInP. Also, the second n-type compound semiconductor layer may include a second n-type clad layer disposed on the second resonant layer and formed of AlGaInP; a second buffer layer disposed on the second n-type clad layer and formed of GaAs; and a GaAs substrate stacked on the second buffer layer.

The third LD may include a third laser oscillation layer including a third resonant layer and a third n-type compound semiconductor layer and a third p-type compound semiconductor layer disposed on both surfaces of the third resonant layer; a third n-type electrode layer and a third p-type electrode layer disposed on both surfaces of the third laser oscillation layer; and a bonding metal layer disposed on one surface of at least one of the third n-type electrode layer and the third p-type electrode layer.

The third p-type compound semiconductor layer may include a third p-type contact layer disposed on the third p-type electrode layer and formed of GaAs; and a third p-type clad layer disposed on the third p-type contact layer and formed of AlGaAs. The third resonant layer may include a third active layer formed of AlGaAs; and third waveguide layers disposed on and under the third active layer and formed of AlGaAs. The third n-type compound semiconductor layer may include a third n-type clad layer disposed on the third resonant layer and formed of AlGaAs; a third buffer layer disposed on the third n-type clad layer and formed of GaAs; and a GaAs substrate stacked on the third buffer layer.

According to another aspect of the present invention, there is provided a multiple-wavelength LD including a first LD; an insulating layer disposed on a substrate that extends from the first LD; and at least a second LD and a third LD bonded onto the insulating layer. In the multiple-wavelength LD, the first, second, and third LDs are aligned such that centers of emission points of the first, second, and third LDs are aligned.

A hit sink may be further installed on one side of the substrate to absorb heat generated from the first, second, and third LDs. The hit sink may be formed of one selected from the group consisting of AlN, SiC, and a metal.

The first LD may include a first laser oscillation layer including a first resonant layer and a first n-type compound semiconductor layer and a first p-type compound semiconductor layer disposed on both surfaces of the first resonant layer; a first n-type electrode layer and a first p-type electrode layer disposed on both surfaces of the first laser oscillation layer; and a bonding metal layer disposed on one surface of at least one of the first n-type electrode layer and the first p-type electrode layer.

The first p-type compound semiconductor layer may include a GaN substrate; a first buffer layer disposed on a predetermined region of the GaN substrate and formed of GaN; and a first n-type clad layer disposed on the first buffer layer and formed of AlGaN. The first resonant layer may include a first active layer formed of InGaN; and first waveguide layers disposed on and under the first active layer and formed of InGaN. Also, the first p-type compound semiconductor layer may include a first p-type clad layer disposed on the first resonant layer and formed of AlGaN; and a first p-type contact layer disposed on the first p-type clad layer and formed of GaN.

The second LD may include a second laser oscillation layer including a second resonant layer and a second n-type compound semiconductor layer and a second p-type compound semiconductor layer disposed on both surfaces of the second resonant layer; a second n-type electrode layer and a second p-type electrode layer disposed on both surfaces of the second laser oscillation layer; and a bonding metal layer disposed on one surface of at least one of the second n-type electrode layer and the second p-type electrode layer.

The second p-type compound semiconductor layer may include a second p-type contact layer disposed on the second p-type electrode layer and formed of GaAs; and a second p-type clad layer disposed on the second p-type contact layer and formed of AlGaInP. The second resonant layer may include a second active layer formed of AlGaInP; and second waveguide layers disposed on and under the second active layer and formed of AlGaInP. Also, the second n-type compound semiconductor layer may include a second n-type clad layer disposed on the second resonant layer and formed of AlGaInP; a second buffer layer disposed on the second n-type clad layer and formed of GaAs; and a GaAs substrate stacked on the second buffer layer.

The third LD may include a third laser oscillation layer including a third resonant layer and a third n-type compound semiconductor layer and a third p-type compound semiconductor layer disposed on both surfaces of the third resonant layer; a third n-type electrode layer and a third p-type electrode layer disposed on both surfaces of the third laser oscillation layer; and a bonding metal layer disposed on one surface of at least one of the third n-type electrode layer and the third p-type electrode layer.

The third p-type compound semiconductor layer may include a third p-type contact layer disposed on the third p-type electrode layer and formed of GaAs; and a third p-type clad layer disposed on the third p-type contact layer and formed of AlGaAs. The third resonant layer may include a third active layer formed of AlGaAs; and third waveguide layers disposed on and under the third active layer and formed of AlGaAs. Also, the third n-type compound semiconductor layer may include a third n-type clad layer disposed on the third resonant layer and formed of AlGaAs; a third buffer layer disposed on the third n-type clad layer and formed of GaAs; and a GaAs substrate stacked on the third buffer layer.

According to yet another aspect of the present invention, there is provided a method for fabricating a multiple-wavelength LD. The method includes preparing at least a first LD, a second LD, and a third LD, each having a first surface and a second surface that face each other; exposing a substrate of the first LD by etching a predetermined region of the first LD to a predetermined depth; forming an insulating layer on the exposed substrate of the first LD; bonding a second surface of the second LD onto the insulating layer; and bonding a second surface of the third LD onto the insulating layer. In this method, the first, second, and third LDs are aligned such that centers of emission points of the first, second, and third LDs are aligned.

A hit sink may be further installed on a first surface of the first LD to absorb heat generated from the first, second, and third LDs. The hit sink may be formed of one selected from the group consisting of AlN, SiC, and a metal.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a multiple-wavelength laser diode (LD) according to an exemplary embodiment of the present invention;

FIG. 2 is an exploded view of a first LD shown in FIG. 1;

FIG. 3 is an exploded view of a second LD shown in FIG. 1;

FIG. 4 is an exploded view of a third LD shown in FIG. 1;

FIG. 5 is a cross-sectional view of a multiple-wavelength LD according to another exemplary embodiment of the present invention; and

FIGS. 6A through 6E are cross-sectional views illustrating a method for fabricating the multiple-wavelength LD shown in FIG. 5.

### DESCRIPTION OF PREFERRED EMBODIMENTS

A multiple-wavelength laser diode (LD) and method of fabricating the same will now be described more fully hereinafter with reference to the accompanying drawings, in which exemplary embodiments of the invention are shown.

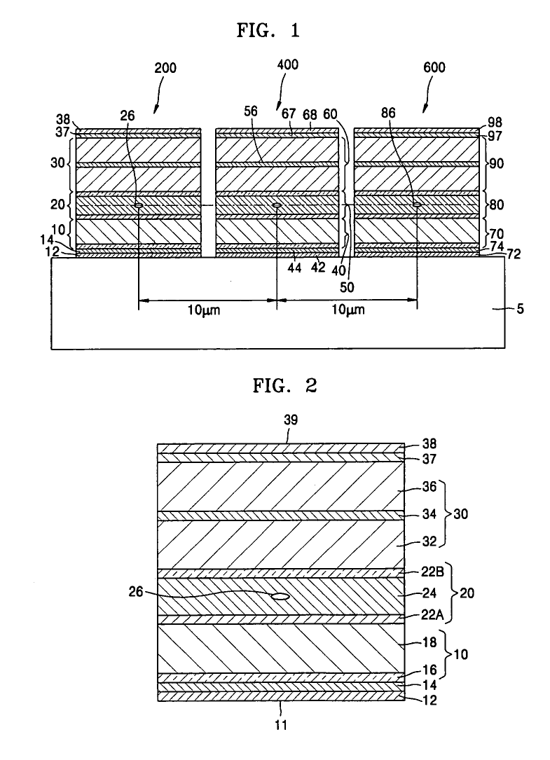

FIG. 1 is a cross-sectional view of a multiple-wavelength LD according to an exemplary embodiment of the present invention, and FIGS. 2, 3, and 4 are exploded views of first, second, and third LDs shown in FIG. 1.

Referring to FIG. 1, at least three LDs, for example, a first LD 200, a second LD 400, and a third LD 600, are bonded onto a plate 5. The first, second, and third LDs 200, 400, and 600 are aligned such that centers of emission points 26, 56, and 86 form a line. Thus, the multiple-wavelength LD can be applied to an optical system that requires a plurality of light sources, and the optical system can be structurally simple. Also, by using the multiple-wavelength LD according to the present invention, a plurality of laser beams of light are easily condensed using a single optical lens, aberration is reduced, and condensing efficiency is enhanced.

The plate 5 is formed of a highly thermal conductive material, that is, any one selected from the group consisting of AlN, SiC, and a metal. Thus, heat generated from the first, second, and third LDs 200, 400, and 600 can be easily radiated through the plate 5. As a result, temperature increase of the first, second, and third LDs 200, 400, and 600 can be inhibited, and thus the useful life thereof can be extended. A hit sink (not shown) may be further disposed on one side of the plate 5 and to increase the efficiency to radiate heat generated from the first, second, and third LDs 200, 400, and 600.

Referring to FIGS. 1 and 2, the first LD 200, which is bonded onto the plate 5, includes a bonding metal layer 12, a first p-type electrode layer 14, a first p-type compound semiconductor layer 10, a first resonant layer 20, a first n-type compound semiconductor layer 30, a first n-type electrode layer 37, and a bonding metal layer 38, which are sequentially stacked.

The first p-type compound semiconductor layer 10 includes a first p-type contact layer 16 and a first p-type clad layer 18. The first p-type contact layer 16 is disposed on the first p-type electrode layer 14 using GaN, and the first p-type clad layer 18 is disposed on the first p-type contact layer 16 using AlGaN. Also, the first resonant layer 20 includes a first active layer 24 and first waveguide layers 22a and 22b disposed under and on the first active layer 24. The first active layer 24 is formed of InGaN, and the first waveguide layers 22a and 22b also are formed of InGaN. Further, the first n-type compound semiconductor layer 30 includes a first n-type clad layer 32, a first buffer layer 34, and a GaN substrate 36. The first n-type clad layer 32 is disposed on the first resonant layer 20 using AlGaN, the first buffer layer 34 is disposed on the first n-type clad layer 32 using GaN, and the GaN substrate 36 is stacked on the first buffer layer 34. A first emission point 26 is disposed in the first active layer 24 and emits a first laser beam. Also, the first LD 200 includes a bottom surface of a stacked structure (e.g., a second surface 11 that corresponds to an outer surface of the bonding metal layer 12) and a top surface of the stacked structure (e.g., a first surface 39 that corresponds to an outer surface of the bonding metal layer 38), and the first and second surfaces 39 and 11 face each other.

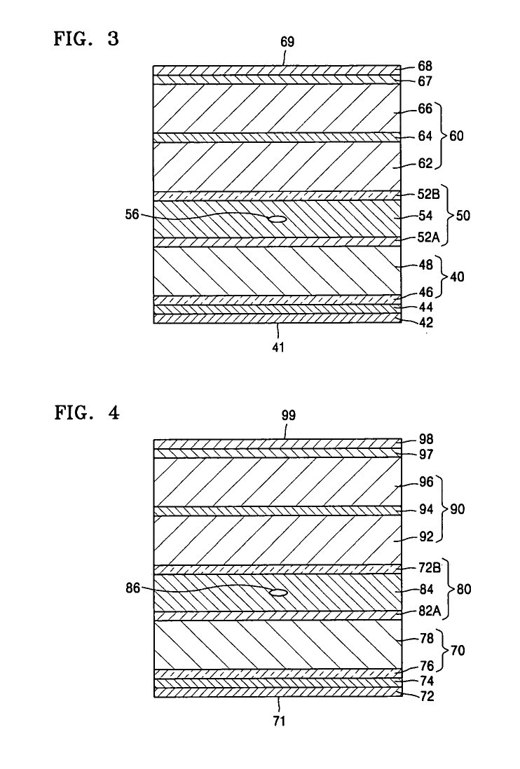

Referring to FIGS. 1 and 3, the second LD 400, which is bonded onto the plate 5, includes a bonding metal layer 42, a second p-type electrode layer 44, a second p-type compound semiconductor layer 40, a second resonant layer 50, a second n-type compound semiconductor layer 60, a second n-type electrode layer 67, and a bonding metal layer 68, which are sequentially stacked.

The second p-type compound semiconductor layer 40 includes a second p-type contact layer 46 and a second p-type clad layer 48. The second p-type contact layer 46 is disposed on the second p-type electrode layer 44 using GaAs, and the second p-type clad layer 48 is disposed on the second p-type contact layer 46 using AlGaInP. Also, the second resonant layer 50 includes a second active layer 54 and second waveguide layers 52a and 52b disposed under and on the second active layer 54. The second active layer 54 is formed of AlGaInP, and the second waveguide layers 52a and 52b also are formed of AlGaInP. Further, the second n-type compound semiconductor layer 60 includes a second n-type clad layer 62, a second buffer layer 64, and a GaAs substrate 66. The second n-type clad layer 62 is disposed on the second resonant layer 50 using AlGaInP, the second buffer layer 64 is disposed on the second n-type clad layer 62 using GaAs, and the GaAs substrate 66 is stacked on the second buffer layer 64. A second emission point 56 is disposed in the second active layer 54 and emits a second laser beam. Also, the second LD 400 includes a bottom surface of a stacked structure (e.g., a second surface 41 that corresponds to an outer surface of the bonding metal layer 42) and a top surface of the stacked structure (e.g., a first surface 69 that corresponds to an outer surface of the bonding metal layer 68), and the first and second surfaces 69 and 41 face each other.

Referring to FIGS. 1 and 4, the second LD 600, which is bonded onto the plate 5, includes a bonding metal layer 72, a third p-type electrode layer 74, a third p-type compound semiconductor layer 70, a third resonant layer 80, a third n-type compound semiconductor layer 90, a third n-type electrode layer 97, and a bonding metal layer 98, which are sequentially stacked.

The third p-type compound semiconductor layer 70 includes a third p-type contact layer 76 and a third p-type clad layer 78. The third p-type contact layer 76 is disposed on the third p-type electrode 74 using GaAs, and the third p-type clad layer 78 is disposed on the third p-type contact layer 76 using AlGaAs. Also, the third resonant layer 80 includes a third active layer 84 and third waveguide layers 82a and 82b disposed under and on the third active layer 84. The third active layer 84 is formed of AlGaAs, and the third waveguide layers 82a and 82b also are formed of AlGaAs. Further, the third n-type compound semiconductor layer 90 includes a third n-type clad layer 92, a third buffer layer 94, and a GaAs substrate 96. The third n-type clad layer 92 is disposed on the third resonant layer 80 using AlGaAs, the third buffer layer 94 is disposed on the third n-type clad layer 92 using GaAs, and the GaAs substrate 96 is stacked on the third buffer layer 94. A third emission point 86 is disposed in the third active layer 84 and emits a third laser beam. Also, the third LD 600 includes a bottom surface of a stacked structure (e.g., a second surface 71 that corresponds to an outer surface of the bonding metal layer 72) and a top surface of the stacked structure (e.g., a first surface 99 that corresponds to an outer surface of the bonding metal layer 98), and the first and second surfaces 99 and 71 face each other.

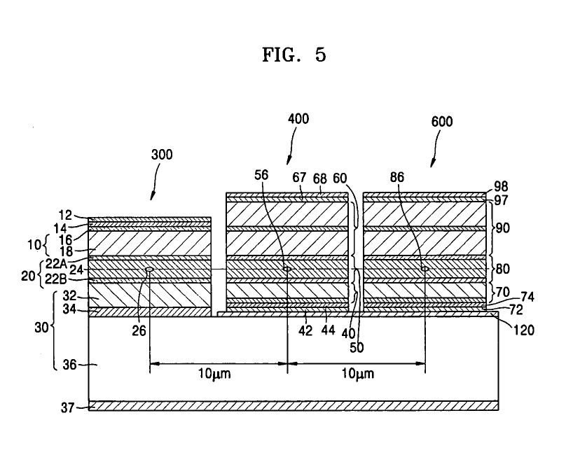

FIG. 5 is a cross-sectional view of a multiple-wavelength LD according to another exemplary embodiment of the present invention.

Referring to FIG. 5, a first LD 300 is disposed, and a GaN substrate 36 extends from the first LD 300 in a lengthwise direction. An insulating layer 120 is disposed on the extending portion of the GaN substrate 36, and a second LD 400 and a third LD 600 are bonded onto the insulating layer 120. The first, second, and third LDs 300, 400, and 600 are aligned such that centers of emission points 26, 56, and 86 form a line. In this case, the insulating layer 120 electrically isolates the second and third LDs 400 and 600 from the first LD 300.

A hit sink (not shown), which is formed of a highly thermally conductive material, may be further installed on one surface of the GaN substrate 36 of the first LD 300. The hit sink serves to absorb heat generated from the first, second, and third LDs 300, 400, and 600. The hit sink is selected from the group consisting of AlN, SiC, and a metal.

The first LD 300 includes the same layers as the first LD 200 shown in FIG. 2, but the layers are stacked in the reverse order to the first LD 200 shown in FIG. 2. Here, a description of the same elements as shown in FIG. 2 will be omitted, and the same reference numerals are used to denote the same elements.

The first LD 300 includes a first n-type compound semiconductor layer 30, a third resonant layer 20, a first p-type compound semiconductor layer 10, a first p-type electrode layer 14, and a bonding metal layer 12, which are sequentially stacked. Also, a first n-type electrode layer 37 is disposed on a bottom surface of the first n-type compound semiconductor layer 30 to correspond to the first p-type electrode layer 14.

The first n-type compound semiconductor layer 30 includes a GaAs substrate 36, a first buffer layer 34, and a first n-type clad layer 32. The first buffer layer 34 is disposed on a predetermined region of the GaAs substrate 36 using GaN, and the first n-type clad layer 32 is disposed on the first buffer layer 34 using AlGaN. Also, the first resonant layer 20 includes a first active layer 24 and first waveguide layers 22a and 22b disposed on and under the first active layer 24, respectively. The first active layer 24 is formed of InGaN, and the first waveguide layers 22a and 22b also are formed of InGaN. Further, the first p-type compound semiconductor layer 10 includes a first p-type clad layer 18 and a first p-type contact layer 16. The first p-type clad layer 18 is disposed on the first resonant layer 20 using AlGaN, and the first p-type contact layer 16 is disposed on the first p-type clad layer 18 using GaN.

The second and third LDs 400 and 600, which are bonded onto the insulating layer 120, are the same as the second and third LDs 400 and 600 shown in FIGS. 3 and 4, respectively. Thus, a description of the second and third LDs 400 and 600 will be omitted here.

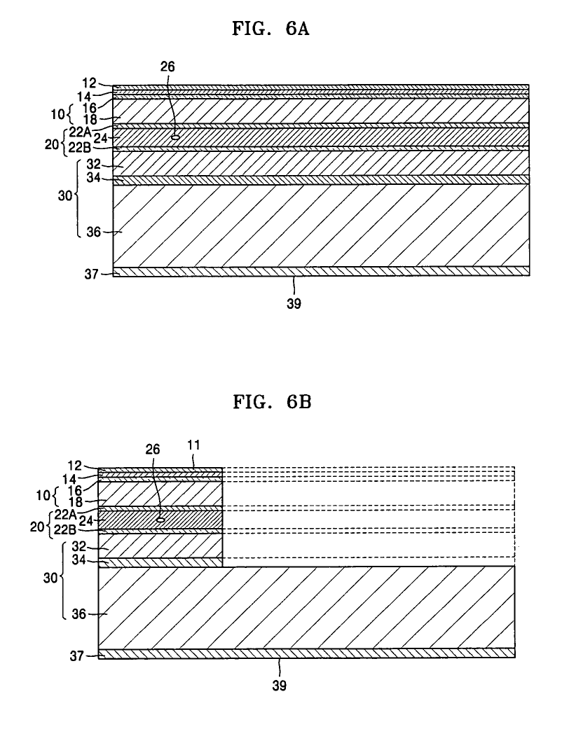

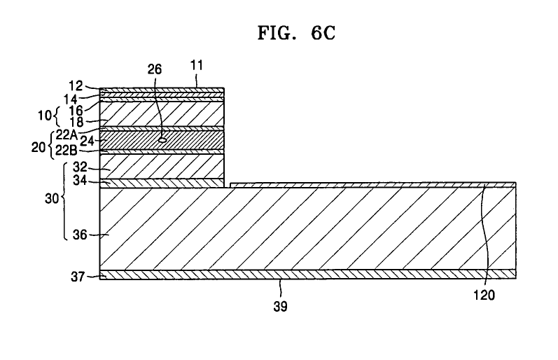

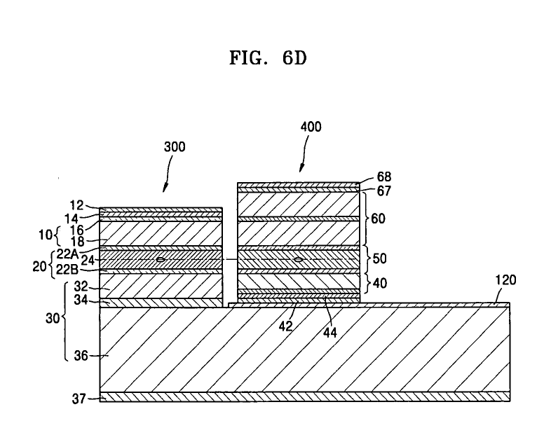

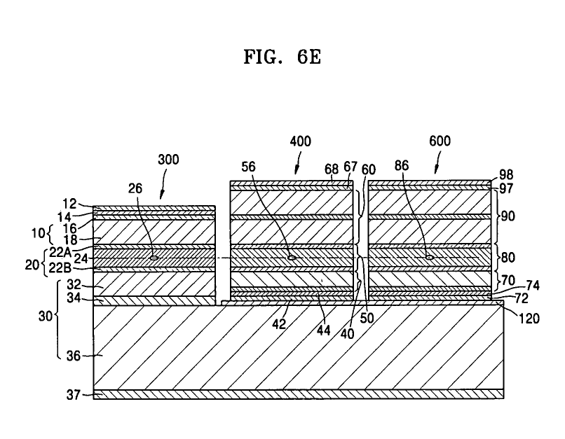

FIGS. 6A through 6E are cross-sectional views illustrating a method of fabricating the multiple-wavelength LD shown in FIG. 5.

Referring to FIG. 6A, a first LD 300 is prepared. The first LD 300 is structurally the same as the first LD 200 shown in FIG. 2 except that layers are stacked in the reverse order to the first LD 200 shown in FIG. 2 and a bonding metal layer 38 is omitted. Thus, a description of the same elements as shown in FIG. 2 will be omitted here, and the same reference numerals are used to denote the same elements.

Referring to FIG. 6B, a predetermined region of the first LD 300 is etched to a predetermined depth. For example, predetermined portions of a second surface 11 through a first buffer layer 34 are etched to expose the surface of a GaN substrate 36 of the first LD 300.

Referring to FIG. 6C, an insulating layer 120 is formed on the exposed surface of the GaN substrate 36 of the first LD 300. The insulating layer 120 may be formed using a known thin-film deposition method.

Referring to FIG. 6D, a second LD 400, which is the same as in FIG. 3, is prepared, and a second surface 41 of the second LD 400 is bonded onto the insulating layer 120. In this case, the first and second LDs 300 and 400 are aligned such that centers of first and second emission points 26 and 56 form a line. In order that the centers of the first and second emission points 26 and 56 may form a line, the insulating layer 120 or the GaN substrate 36, which underlies the insulating layer 120, may be further etched to a predetermined depth.

Referring to FIG. 6E, a third LD 600, which is the same as in FIG. 4, is prepared, and a second surface 71 of the third LD 600 is bonded onto the insulating layer 120. In this case, the first, second, and third LDs 300, 400, and 600 are aligned such that centers of emission points 26, 56, and 86 form a line. In order that the centers of the emission points 26, 56, and 86 may form a line, the insulating layer 120 or the GaN substrate 36, which underlies the insulating layer 120, may be further etched to a predetermined depth.

The multiple-wavelength LD according to the present invention includes at least three laser sources, which are aligned with each other. Thus, when the multiple-wavelength LD is applied to an optical system that requires a plurality of light sources, the optical system can be structurally simple. According to the present invention, since a distance between two adjacent laser sources is very small, a plurality of laser beams are easily condensed using a single optical lens, aberration is reduced, and condensing efficiency is enhanced.

Also, since at least three LDs are disposed on a plate, heat generated from the LDs can be easily radiated through the plate. Therefore, increase in the temperatures of the LDs is inhibited so that the lifetimes of the LDs can be extended.

Further, the present invention provides a simple method of fabricating the multiple-wavelength LD having the above-described benefits.

Moreover, the multiple-wavelength LD according to the present invention can be employed as a light source for an optical pickup that serves to write and reproduce data in blue-ray disks (BDs), digital versatile disks (DVDs), or compact disks (CDs).

While the present invention has been particularly shown and described with reference to exemplary embodiments thereof, it will be understood by those of ordinary skill in the art that various changes in form and in detail may be made therein without departing from the spirit and scope of the present invention as defined by the following claims.

What is claimed is:

1. A multiple-wavelength laser diode comprising at least a first laser diode, a second laser diode, and a third laser diode that are bonded onto a plate and aligned such that centers of emission points of the first, second, and third laser diodes are aligned.

2. The laser diode of claim 1, wherein the plate is selected from the group consisting of AlN, SiC, and a metal.

3. The laser diode of claim 1, wherein the first laser diode comprises:
a first laser oscillation layer including a first resonant layer and a first n-type compound semiconductor layer and a first p-type compound semiconductor layer disposed on both surfaces of the first resonant layer;
a first n-type electrode layer and a first p-type electrode layer disposed on both surfaces of the first laser oscillation layer; and
a bonding metal layer disposed on one surface of at least one of the first n-type electrode layer and the first p-type electrode layer.

4. The laser diode of claim 3, wherein the first p-type compound semiconductor layer includes:
a first p-type contact layer disposed on the first p-type electrode layer formed of GaN; and
a first p-type clad layer disposed on the first p-type contact layer formed of AlGaN,
wherein the first resonant layer includes:
a first active layer formed of InGaN; and
first waveguide layers disposed on and under the first active layer formed of InGaN,
and wherein the first n-type compound semiconductor layer includes:
a first n-type clad layer disposed on the first resonant layer formed of AlGaN;
a first buffer layer disposed on the first n-type clad layer formed of GaN; and
a GaN substrate stacked on the first buffer layer.

5. The laser diode of claim 1, wherein the second laser diode comprises:
a second laser oscillation layer including a second resonant layer and a second n-type compound semiconductor layer and a second p-type compound semiconductor layer disposed on both surfaces of the second resonant layer;
a second n-type electrode layer and a second p-type electrode layer disposed on both surfaces of the second laser oscillation layer; and
a bonding metal layer disposed on one surface of at least one of the second n-type electrode layer and the second p-type electrode layer.

6. The laser diode of claim 5, wherein the second p-type compound semiconductor layer includes:
a second p-type contact layer disposed on the second p-type electrode layer formed of GaAs; and
a second p-type clad layer disposed on the second p-type contact layer formed of AlGaInP,
wherein the second resonant layer includes:
a second active layer formed of AlGaInP; and
second waveguide layers disposed on and under the second active layer formed of AlGaInP,
and wherein the second n-type compound semiconductor layer includes:
a second n-type clad layer disposed on the second resonant layer formed of AlGaInP;
a second buffer layer disposed on the second n-type clad layer formed of GaAs; and
a GaAs substrate stacked on the second buffer layer.

7. The laser diode of claim 1, wherein the third laser diode comprises:
a third laser oscillation layer including a third resonant layer and a third n-type compound semiconductor layer and a third p-type compound semiconductor layer disposed on both surfaces of the third resonant layer;
a third n-type electrode layer and a third p-type electrode layer disposed on both surfaces of the third laser oscillation layer; and
a bonding metal layer disposed on one surface of at least one of the third n-type electrode layer and the third p-type electrode layer.

8. The laser diode of claim 7, wherein the third p-type compound semiconductor layer includes:
a third p-type contact layer disposed on the third p-type electrode layer formed of GaAs; and
a third p-type clad layer disposed on the third p-type contact layer formed of AlGaAs,
wherein the third resonant layer includes:
a third active layer formed of AlGaAs; and
third waveguide layers disposed on and under the third active layer formed of AlGaAs,
and wherein the third n-type compound semiconductor layer includes:
a third n-type clad layer disposed on the third resonant layer formed of AlGaAs;
a third buffer layer disposed on the third n-type clad layer formed of GaAs; and
a GaAs substrate stacked on the third buffer layer.

9. A multiple-wavelength laser diode comprising:
a first laser diode;
an insulating layer disposed on a substrate that extends from the first laser diode; and
at least a second laser diode and a third laser diode bonded onto the insulating layer,
wherein the first, second, and third laser diodes are aligned such that centers of emission points of the first, second, and third laser diodes are aligned.

10. The laser diode of claim 9, further comprising a hit sink installed on one side of the substrate to absorb heat generated from the first, second, and third laser diodes.

11. The laser diode of claim 10, wherein the hit sink is selected from the group consisting of AlN, SiC, and a metal.

12. The laser diode of claim 9, the first laser diode comprises:
a first laser oscillation layer including a first resonant layer and a first n-type compound semiconductor layer and a first p-type compound semiconductor layer disposed on both surfaces of the first resonant layer;
a first n-type electrode layer and a first p-type electrode layer disposed on both surfaces of the first laser oscillation layer; and
a bonding metal layer disposed on one surface of at least one of the first n-type electrode layer and the first p-type electrode layer.

13. The laser diode of claim 12, wherein the first p-type compound semiconductor layer includes:
a GaN substrate;
a first buffer layer disposed on a predetermined region of the GaN substrate formed of GaN; and
a first n-type clad layer disposed on the first buffer layer formed of AlGaN,
wherein the first resonant layer includes:
a first active layer formed of InGaN; and
first waveguide layers disposed on and under the first active layer formed of InGaN,
and wherein the first p-type compound semiconductor layer includes:
a first p-type clad layer disposed on the first resonant layer formed of AlGaN; and
a first p-type contact layer disposed on the first p-type clad layer formed of GaN.

14. The laser diode of claim 9, wherein the second laser diode comprises:
a second laser oscillation layer including a second resonant layer and a second n-type compound semiconductor layer and a second p-type compound semiconductor layer disposed on both surfaces of the second resonant layer;
a second n-type electrode layer and a second p-type electrode layer disposed on both surfaces of the second laser oscillation layer; and
a bonding metal layer disposed on one surface of at least one of the second n-type electrode layer and the second p-type electrode layer.

15. The laser diode of claim 14, wherein the second p-type compound semiconductor layer includes:
a second p-type contact layer disposed on the second p-type electrode layer formed of GaAs; and
a second p-type clad layer disposed on the second p-type contact layer formed of AlGaInP,
wherein the second resonant layer includes:
a second active layer formed of AlGaInP; and
second waveguide layers disposed on and under the second active layer formed of AlGaInP,
and wherein the second n-type compound semiconductor layer includes:
a second n-type clad layer disposed on the second resonant layer formed of AlGaInP;
a second buffer layer disposed on the second n-type clad layer formed of GaAs; and
a GaAs substrate stacked on the second buffer layer.

16. The laser diode of claim 9, wherein the third laser diode comprises:
a third laser oscillation layer including a third resonant layer and a third n-type compound semiconductor layer and a third p-type compound semiconductor layer disposed on both surfaces of the third resonant layer;
a third n-type electrode layer and a third p-type electrode layer disposed on both surfaces of the third laser oscillation layer; and
a bonding metal layer disposed on one surface of at least one of the third n-type electrode layer and the third p-type electrode layer.

17. The laser diode of claim 16, wherein the third p-type compound semiconductor layer includes:
a third p-type contact layer disposed on the third p-type electrode layer formed of GaAs; and
a third p-type clad layer disposed on the third p-type contact layer formed of AlGaAs,
wherein the third resonant layer includes:
a third active layer formed of AlGaAs; and
third waveguide layers disposed on and under the third active layer formed of AlGaAs,
and wherein the third n-type compound semiconductor layer includes:
a third n-type clad layer disposed on the third resonant layer formed of AlGaAs;
a third buffer layer disposed on the third n-type clad layer formed of GaAs; and
a GaAs substrate stacked on the third buffer layer.

18. A method of fabricating a multiple-wavelength laser diode, the method comprising:
preparing at least a first laser diode, a second laser diode, and a third laser diode, each having a first surface and a second surface that face each other;
exposing a substrate of the first laser diode by etching a predetermined region of the first laser diode to a predetermined depth;
forming an insulating layer on the exposed substrate of the first laser diode;
bonding a second surface of the second laser diode onto the insulating layer; and
bonding a second surface of the third laser diode onto the insulating layer,
wherein the first, second, and third laser diodes are aligned such that centers of emission points of the first, second, and third laser diodes are aligned.

19. The method of claim 18, further comprising installing a hit sink on a first surface of the first laser diode to absorb heat generated from the first, second, and third laser diodes.

20. The method of claim 19, wherein the hit sink is selected from the group consisting of AlN, SiC, and a metal.
